(19) United States
(12) Patent Application Publication
(10) Pub. No.: US 2026/0180224 A1
(43) Pub. Date: Jun. 25, 2026

(54) Foldable Plug

(71) Applicant: Anker Innovations Technology Co., Ltd., Changsha (CN)

(72) Inventors: Wei Xie, Shenzhen (CN); Jing Qian, Shenzhen (CN)

(21) Appl. No.: 19/541,590

(22) Filed: Feb. 17, 2026

Related U.S. Application Data
(63) Continuation of application No. PCT/CN2024/105905, filed on Jul. 17, 2024.

(30) Foreign Application Priority Data
Aug. 22, 2023 (CN) 202322262585.1

(51) Int. Cl. H01R 13/11; H01R 13/502; H01R 13/514; H01R 13/627; H01R 13/639; H01R 103/00; H05K 7/14

(52) U.S. Cl. CPC H01R 13/111; H01R 13/502; H01R 13/514; H01R 13/6275; H01R 13/639; H05K 7/1489; H01R 2103/00

(57) ABSTRACT

Disclosed is a plug including a housing, a pin assembly, and a first transmission mechanism. The pin assembly includes a mounting bracket and two pins. The mounting bracket is connected to the housing, and the two pins are rotatably connected to the mounting bracket via rotary shafts to switch between an unfolded position and a stored position. When one of the two pins rotates, the other of the two pins is driven to rotate via a transmission mechanism.

### CROSS-REFERENCE TO RELATED APPLICATIONS

The present disclosure claims priority to PCT/CN2024/105905, filed on Jul. 17, 2024, which claims priority of Chinese Patent Application No. 202322262585.1 filed on Aug. 22, 2023, and entitled “Plug.” Each of the above applications is incorporated herein by reference in its entirety.

### FIELD

The present disclosure relates to the technical field of charging equipment, particularly to a plug.

### BACKGROUND

With the development of technology, there are more and more types of electronic products, and there are also more and more plugs used for electronic products. By inserting pins of a plug into a socket, an electronic product can be charged.

However, the pins are generally long, and an overall size of the plug is thus large, making the plug inconvenient to carry and store.

### SUMMARY

The present disclosure provides a plug that can reduce the overall size of the plug when there is no need to use the pins, making the plug convenient to carry and store.

In a first aspect, the present disclosure provides a plug comprising a housing, a pin assembly, and a transmission mechanism. The pin assembly comprises a mounting bracket and two pins (e.g., spaced apart from each other). The mounting bracket is connected to the housing, and the pins are rotatably connected to the mounting bracket via rotary shafts to switch between an unfolded position and a stored position. An axial direction of the rotary shafts is perpendicular to a plug-in direction of the pins. When the pins are in the unfolded position, a longitudinal direction of the pins is parallel to the plug-in direction of the pins. When the pins are in the stored position, the longitudinal direction of the pins intersects with the plug-in direction of the pins. The transmission mechanism is disposed on the mounting bracket. The two pins are in transmission connection via the transmission mechanism. In response to rotation of one of the pins, the other of the pins is driven to rotate via the transmission mechanism, such that when one of the pins rotates to the unfolded position, the other of the pins is driven to rotate to the unfolded position, and when one of the pins rotates to the stored position, the other of the pins is driven to rotate to the stored position.

In a second aspect, the present disclosure further provides a plug comprising a housing, a pin assembly, and a transmission mechanism. The pin assembly comprises a mounting bracket and two pins made of metal material. The mounting bracket is connected to the housing, and the pins are rotatably connected to the mounting bracket via rotary shafts to switch between an unfolded position and a stored position. An axial direction of the rotary shafts is perpendicular to a plug-in direction of the pins. When the pins are in the unfolded position, a longitudinal direction of the pins is parallel to the plug-in direction of the pins. When the pins are in the stored position, the longitudinal direction of the pins intersects with the plug-in direction of the pins. The transmission mechanism is disposed on the mounting bracket. The two pins are in transmission connection via the transmission mechanism. In response to rotation of one of the pins, the other of the pins is driven to rotate via the first transmission mechanism, such that when one of the pins rotates to the unfolded position, the other of the pins is driven to rotate to the unfolded position, and when one of the pins rotates to the stored position, the other of the pins is driven to rotate to the stored position.

According to the plug of the examples of the disclosure, when the pins need to be used, the pins are rotated to the unfolded position, at which time a part of the pins protruding from the housing is long, facilitating insertion of the pins into the socket in the plug-in direction. When there is no need to use the pins, the pins are rotated to the stored position for storage, at which time the part of the pins protruding from the housing is short, which may reduce the overall size of the plug, making the plug convenient to carry and store. In addition, the two pins may be linked via the first transmission mechanism, such that rotating either one of the pins may drive the other of the pins to rotate, without a user adjusting positions of the two pins separately, making the pins more convenient to use.

### BRIEF DESCRIPTION OF THE DRAWINGS

In order to more clearly illustrate technical solutions in examples of the present disclosure or in the related art, drawings that need to be used in description of the examples or the related art are briefly introduced below. The drawings in the following description are merely some examples of the disclosure, and other drawings can be obtained in accordance with these drawings without inventive work for those skilled in the art.

FIG. 1 is a structure diagram of a plug according to an example of the present disclosure in which a rotary bracket is in a first preset position, a mounting bracket is in a third preset position, and pins are in an unfolded position;

FIG. 2 is a structure diagram of a plug according to an example of the present disclosure in which a rotary bracket is in a first preset position, a mounting bracket is in a third preset position, pins are in a stored position, and a distance-increasing safety member is in a distance-decreasing position;

FIG. 3 is a partial structure diagram of a plug interior from a first viewing angle according to an example of the present disclosure in which a rotary bracket is in a first preset position, a mounting bracket is in a third preset position, and pins are in an unfolded position;

FIG. 4 is a structure diagram of a rotary bracket and a pin assembly according to an example of the present disclosure in which a mounting bracket is in a third preset position, pins are in a stored position, and a distance-increasing safety member is in a distance-decreasing position;

FIG. 5 is a partial structure diagram of a plug interior according to an example of the present disclosure from a second viewing angle in which a rotary bracket is in a first preset position, a mounting bracket is in a third preset position, pins are in an unfolded position, and a distance-increasing safety member is in a distance-increasing position;

FIG. 6 is a partial structure diagram of a plug interior according to an example of the present disclosure from a third viewing angle in which a rotary bracket is in a first preset position, a mounting bracket is in a third preset position, and pins are in an unfolded position;

FIG. 7 is a structure diagram of some components of a pin assembly according to an example of the present disclosure;

FIG. 8 is an exploded view of some components of a pin assembly according to an example of the present disclosure;

FIG. 9 is a structure diagram of a plug according to an example of the present disclosure in which a rotary bracket is in a second preset position, a mounting bracket is in a third preset position, and pins are in an unfolded position;

FIG. 10 is a structure diagram of a plug according to an example of the present disclosure in which a rotary bracket is in a first preset position, a mounting bracket is in a fourth preset position, and pins are in an unfolded position;

FIG. 11 is an exploded view of components of a plug according to an example of the present disclosure;

FIG. 12 is an exploded view of some components of a plug according to an example of the present disclosure; and

FIG. 13 is an exploded view of some components of a plug according to an example of the present disclosure.

### DESCRIPTION OF REFERENCE SIGNS

10: housing; 11: first mounting recess; 12: peripheral surface; 13: main body; 14: fixed bracket; 141: through hole; 20: pin assembly; 21: pin; 22: mounting bracket; 23: silicone seat; 24: first rotary shaft; 25: distance-increasing safety member; 26: second rotary shaft; 30: rotary bracket; 31: second mounting recess; 32: elastic bracket; 321: second elastic piece; 33: rotary arm; 40: rotary assembly; 41: bushing; 42: first elastic piece; 421: concave-convex structure; 43: positioning piece; 44: positioning plate; 51: circuit board; 52: conductive wire; 60: accommodating recess; 70: first transmission mechanism; 71: first driving gear; 72: second driving gear; 73: first transmission gear; 74: second transmission gear; 80: second transmission mechanism; 81: third driven gear; 82: rack; 83: slide rod; 84: slide groove; 85: transition gear.

### DETAILED DESCRIPTION

In order to make the object, technical solutions and advantages of the present disclosure clearer and more understandable, the present disclosure will be described in further detail below with reference to the accompanying drawings. It should be understood that the specific examples described herein are only used to explain the disclosure and but not used to limit the disclosure.

The present disclosure describes a plug that solves the problem in the related art. In the related art, the pins are generally long, and an overall size of the plug is thus large, making the plug inconvenient to carry and store.

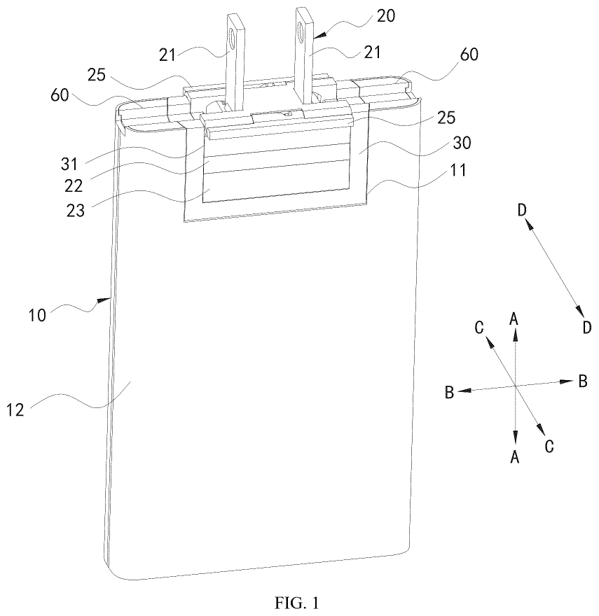

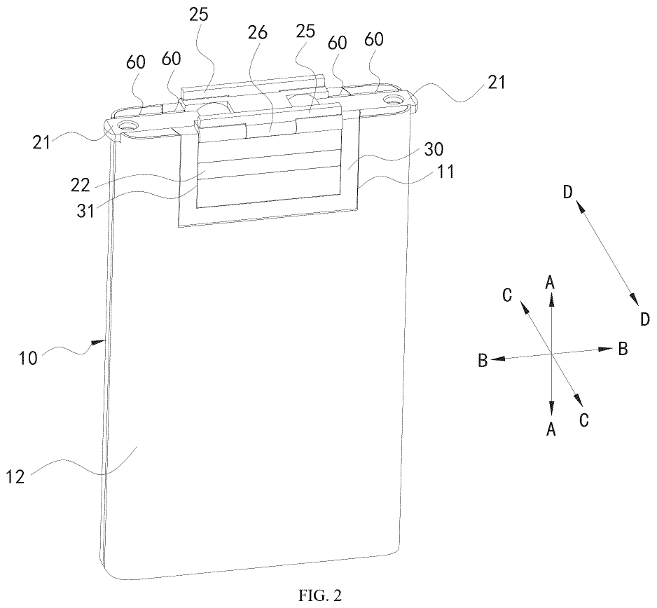

As illustrated in FIGS. 1 and 2, a plug includes a housing 10 and a pin assembly 20. The plug may be provided on charging products such as chargers, power banks, and sockets. The housing 10 is configured to provide support and protection for components such as the pin assembly 20. An overall shape of the housing 10 may be a cuboid, cube, cylinder or other shapes, which is not specifically limited by the present disclosure. The pin assembly 20 may include two spaced-apart pins 21 made of metal material. The pins 21 are configured to be inserted into a socket to achieve electrical connection between the plug and a device to be charged, thereby achieving electrical connection between a power supply and the device to be charged. The device to be charged may be a mobile phone, a tablet computer, a gaming device, an augmented reality (AR) device, a data storage device, an audio playback device, a video playback device, a desktop computing device, or a wearable device. The wearable device may be an electronic watch, electronic glasses, an electronic helmet, an electronic bracelet, an electronic necklace, or the like.

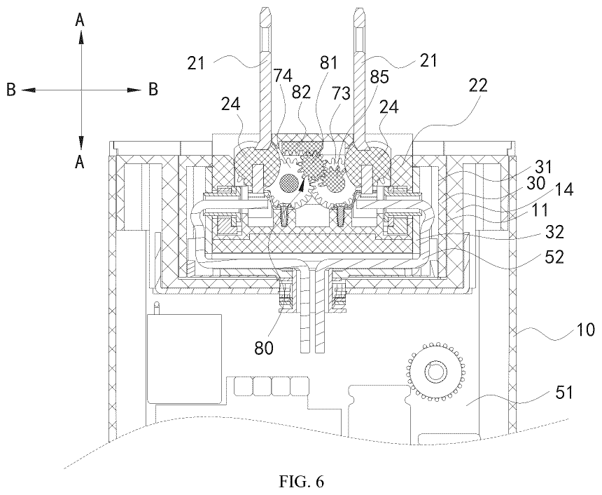

In an example, the pin assembly 20 further includes a mounting bracket 22 that is connected to the housing 10. The pins 21 are rotatably connected to the mounting bracket 22 via a first rotary shaft 24 (as illustrated in FIG. 6) to switch between an unfolded position (as illustrated in FIG. 1) and a stored position (as illustrated in FIG. 2). The first rotary shaft 24 may comprise two rotary shafts corresponding to the two pins 21. An axial direction of the first rotary shaft 24 is perpendicular to a plug-in direction of the pins 21. It should be noted that the pins 21 can rotate relative to the mounting bracket 22, and the plug-in direction of the pins 21 refers to a direction in which the pins are inserted into a socket.

When the pins 21 are in the unfolded position, a longitudinal direction of the pins 21 is parallel to the plug-in direction of the pins 21. When the pins 21 are in the stored position, the longitudinal direction of the pins 21 intersects with the plug-in direction of the pins 21. Understandably, the longitudinal direction of the pins 21 may be perpendicular to the plug-in direction of the pins 21, and the longitudinal direction of the pins 21 may form an included angle of another angle with the plug-in direction of the pins 21, such as 30 degrees, 45 degrees, 60 degrees, or 75 degrees. As illustrated in FIG. 1, when the pins 21 need to be used, the pins 21 are rotated to the unfolded position. At this time, a part of the pins 21 protruding from the housing 10 is long, facilitating insertion of the pins 21 into the socket in the plug-in direction. As illustrated in FIG. 2, when there is no need to use the pins 21, the pins 21 are rotated to the stored position for storage. At this time, the part of the pins 21 protruding from the housing 10 is short, which may reduce the overall size of the plug, making the plug convenient to carry and store.

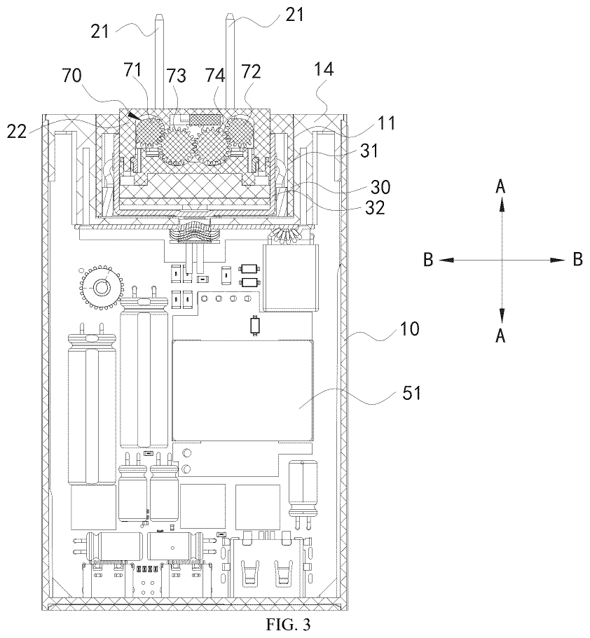

In an example, as illustrated in FIG. 3, the plug also includes a first transmission mechanism 70 that is disposed on the mounting bracket 22. The two pins 21 are in transmission connection via the first transmission mechanism 70. When one of the pins 21 rotates, the other of the pins 21 is driven to rotate via the first transmission mechanism 70. When one of the pins 21 rotates to the unfolded position, the other of the pins 21 is driven to rotate to the unfolded position. When one of the pins 21 rotates to the stored position, the other of the pins 21 is driven to rotate to the stored position. Understandably, the two pins 21 may be linked via the first transmission mechanism 70, such that rotating either one of the pins 21 drives the other of the pins 21 to rotate, without a user adjusting positions of the two pins 21 separately, making the pins 21 more convenient to use.

Referring again to FIGS. 1 to 3, in some examples of the present disclosure, the housing 10 and/or the mounting bracket 22 is provided with an accommodating recess 60. The accommodating recess 60 is configured to accommodate the pins 21 when the rotary bracket 30 is in the stored position. When the pins 21 are in the unfolded position, the pins 21 extend in a direction away from a bottom wall of the accommodating recess 60, and heads of the pins 21 are located outside the accommodating recess 60. When the pins 21 need to be used, the pins 21 are rotated to the unfolded position. At this time, the heads of the pins 21 are located outside the accommodating recess 60, and the pins 21 may be inserted into a power strip. When there is no need to use the plug, the pins 21 may be rotated into the accommodating recess 60 for storage, which may further reduce the overall size of the plug, making the plug convenient to carry and store.

It should also be noted that the accommodating recess 60 may be provided only in the housing 10 or the mounting bracket 22 or in both the housing 10 and the mounting bracket 22. It should also be noted that the number of accommodating recesses 60 is the same as the number of pins 21, and the accommodating recesses 60 are in one-to-one correspondence with the pins 21. When there are two pins 21, there are also two accommodating recesses 60, each of which is configured to accommodate a different pin 21.

In an example, as illustrated in FIG. 3, the first transmission mechanism 70 includes a first driving gear 71, a second driving gear 72, a first transmission gear 73, and a second transmission gear 74.

The first driving gear 71 is connected to the first rotary shaft 24 of one of the pins 21, and an axial direction of the first driving gear 71 is parallel to the axial direction of the first rotary shaft 24. The second driving gear 72 is connected to the first rotary shaft 24 of the other of the pins 21, and an axial direction of the second driving gear 72 is parallel to the axial direction of the first rotary shaft 24. The first transmission gear 73 is rotatably connected to the mounting bracket 22 about an axial direction of the first transmission gear 73, the axial direction of the first transmission gear 73 is parallel to the axial direction of the first rotary shaft 24, and the first transmission gear 73 meshes with the first driving gear 71. The second transmission gear 74 is rotatably connected to the mounting bracket 22 about an axial direction of the second transmission gear 74, the axial direction of the second transmission gear 74 is parallel to the axial direction of the first rotary shaft 24, and the second transmission gear 74 meshes with the first transmission gear 73 and the second driving gear 72.

It should be noted that when the pin 21 corresponding to the first driving gear 71 is rotated, the first driving gear 71 drives the first transmission gear 73 to rotate, the first transmission gear 73 drives the second transmission gear 74 to rotate, and the second transmission gear 74 drives the second driving gear 72 to rotate, thereby causing the pin 21 corresponding to the second driving gear 72 to rotate. In addition, understandably, the two driving gears are connected by the two transmission gears, so that the two pins 21 rotate in opposite directions. For example, when one of the pins 21 rotates clockwise, the other of the pins 21 is driven to rotate counterclockwise. This allows the two pins 21 to rotate in directions away from each other when rotating from the unfolded position to the stored position, so as to prevent the two pins 21 from hindering each other's rotation when a distance between the two pins 21 is small. For example, the number of teeth of the first driving gear 71 is the same as the number of teeth of the second driving gear 72, and the number of teeth of the first transmission gear 73 is the same as the number of teeth of the second transmission gear 74, so that the first pin 21 and the second pin 21 can rotate synchronously.

It should also be noted that, depending on actual needs, the first transmission mechanism 70 may be other transmission mechanisms. For example, the transmission mechanism 70 may be a mechanical transmission mechanism, such as a linkage transmission mechanism, a belt transmission mechanism, or a chain transmission mechanism. The first transmission mechanism 70 may also be an electrical transmission mechanism that includes electrical equipment such as an electric motor or a cylinder.

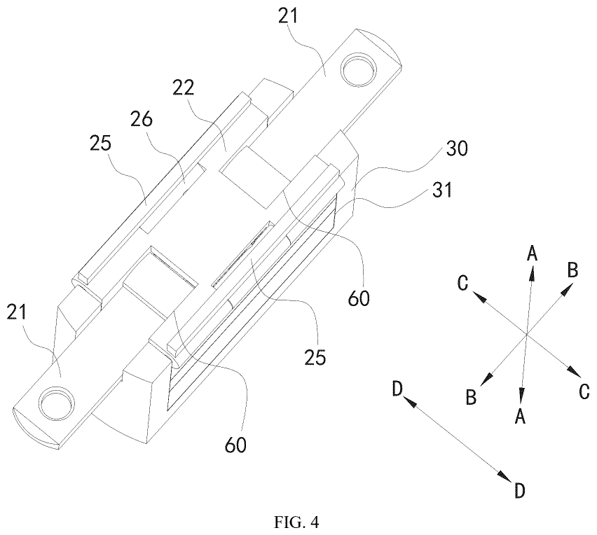

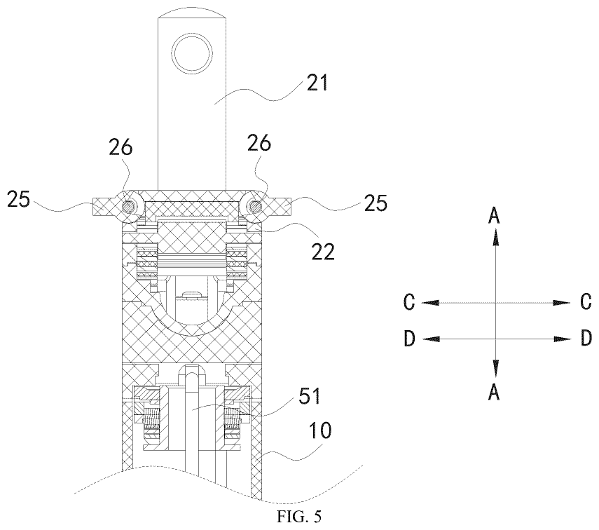

As illustrated in FIGS. 4 and 5, in some examples of the present disclosure, the pin assembly 20 further includes distance-increasing safety members 25. The distance-increasing safety members 25 are disposed on two sides of the pins 21 along the axial direction of the first rotary shaft 24, disposed at edges of the mounting bracket 22, and configured to increase a length of the pins 21 along the axial direction of the first rotary shaft 24. It should be noted that the distance-increasing safety member 25 is made of an insulating material. When the pins 21 are in the unfolded position, the distance-increasing safety members 25 can increase the length of the pins 21 along the axial direction of the first rotary shaft 24, so that when the user holds the plug, the distance-increasing safety members 25 can increase a distance between the fingers and the pins 21, preventing the fingers from contacting the pins 21 and causing electric shock.

In an example of the present disclosure, the distance-increasing safety member 25 is rotatably connected to the mounting bracket 22 via a second rotary shaft 26 (as illustrated in FIG. 5) to switch between a distance-increasing position (as illustrated in FIG. 5) and a distance-decreasing position (as illustrated in FIG. 4). An axial direction of the second rotary shaft 26 is perpendicular to the axial direction of the first rotary shaft 24.

When the distance-increasing safety member 25 is in the distance-increasing position, a length of the pins 21 along the axial direction of the first rotary shaft 24 is L1. When the distance-increasing safety member 25 is in the distance-decreasing position, a length of the pins 21 along the axial direction of the first rotary shaft 24 is L2. L1 is greater than L2.

Understandably, when the plug needs to be used, a distance-increasing safety member 25 can be rotated to a distance-increasing position. At this time, the distance-increasing safety member 25 can increase the length of the pins 21 along the axial direction of the first rotary shaft 24 to prevent the fingers from contacting the pins 21 and causing electric shock. When there is no need to use the plug, the distance-increasing safety member 25 can be rotated to a distance-decreasing position. At this time, the length of the pins 21 along the axial direction of the first rotary shaft 24 is relatively small, which may reduce the overall size of the plug, making the plug convenient to carry and store.

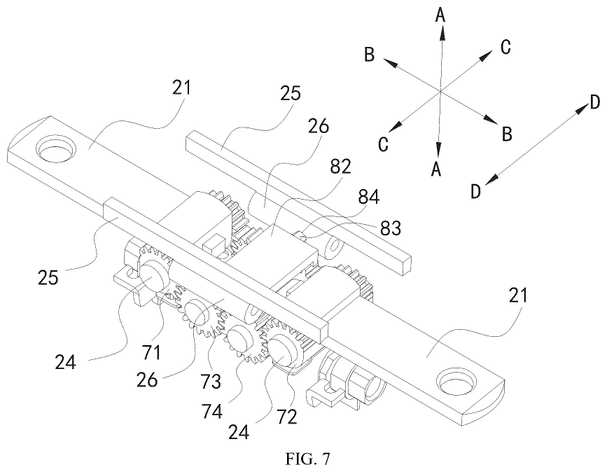

As illustrated in FIGS. 6 and 7, in an example of the present disclosure, the pin assembly 20 further includes a second transmission mechanism 80. The second transmission mechanism 80 is disposed on the mounting bracket 22. The first rotary shaft 24 is in transmission connection with the second rotary shaft 26 via the second transmission mechanism 80. When the first rotary shaft 24 rotates, the second rotary shaft 26 is driven to rotate via the second transmission mechanism 80. When the pins 21 rotate to the unfolded position, the distance-increasing safety member 25 is driven to rotate to the distance-increasing position. When the pins 21 rotate to the stored position, the distance-increasing safety member 25 is driven to rotate to the distance-decreasing position.

Understandably, the pins 21 and the distance-increasing safety member 25 can be linked via the second transmission mechanism 80, so that when the pins 21 are rotated, the distance-increasing safety member 25 can be driven to rotate. When the plug needs to be used, the pins 21 need to be rotated to the unfolded position, and at this time, the distance-increasing safety member 25 is driven to the distance-increasing position. When there is no need to use the plug, the pins 21 need to be rotated to the stored position, and at this time, the distance-increasing safety member 25 is driven to the distance-decreasing position. Accordingly, the distance-increasing safety member 25 is more convenient to use. It should also be noted that the second transmission mechanism 80 may be provided between only one of the pins 21 and the distance-increasing safety member 25, or the second transmission mechanism 80 may be provided between each of the pins 21 and the distance-increasing safety member 25, so that the distance-increasing safety member 25 can be rotated by rotating any one of the pins 21.

Referring to FIGS. 6 to 8, in an example of the present disclosure, the second transmission mechanism 80 includes a third driven gear 81 and a rack 82. The third driven gear 81 is rotatably connected to the mounting bracket 22 about an axial direction of the third driven gear 81, and is in transmission connection with the first rotary shaft 24. The axial direction of the third driven gear 81 is parallel to the axial direction of the first rotary shaft 24. When the first rotary shaft 24 rotates, the third driven gear 81 is driven to rotate. The rack 82 is slidably connected to the mounting bracket 22 along the axial direction of the second rotary shaft 26, and the rack 82 meshes with the third driven gear 81.

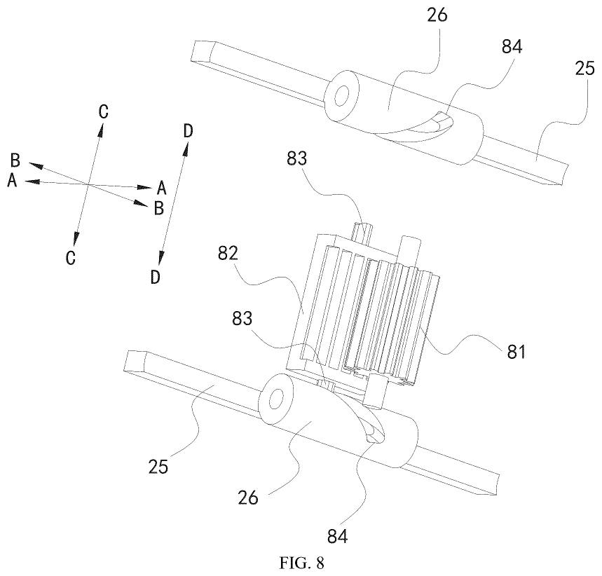

As illustrated in FIGS. 7 and 8, a slide rod 83 is connected to the rack 82, and a slide groove 84 is provided in a circumferential surface of the second rotary shaft 26. The slide groove 84 extends along the axial direction and a circumferential direction of the second rotary shaft 26. The slide rod 83 is inserted into the slide groove 84. When the rack 82 slides along the axial direction of the second rotary shaft 26, the slide rod 83 slides along the slide groove 84 to drive the second rotary shaft 26 to rotate about the axial direction of the second rotary shaft 26.

Understandably, the function of the slide groove 84 is the same as that of the slide groove 84 in a cylindrical cam (the specific principle of the cylindrical cam has been disclosed in the related art and will not be described in detail in the present disclosure). When the pins 21 are rotated, the first rotary shaft 24 drives the third driven gear 81 to rotate, and the third driven gear 81 drives the rack 82 to slide along the axial direction of the second rotary shaft 26. At this time, through the fitting of the slide rod 83 and the slide groove 84, the second rotary shaft 26 is driven to rotate about the axial direction of the second rotary shaft 26, thereby driving the distance-increasing safety member 25 to rotate.

In an example of the present disclosure, as illustrated in FIG. 6, the second transmission mechanism 80 may further include a transition gear 85. The transition gear 85 is coaxially disposed and fixedly connected with the first transmission gear 73 or the second transmission gear 74, and meshes with the third driven gear 81. The first rotary shaft 24 is in transmission connection with the third driven gear 81 via the transition gear 85. When either of the pins 21 is rotated, the first transmission gear 73 and the second transmission gear 74 are driven to rotate, thereby driving the transition gear 85 to rotate and driving the third driven gear 81 to rotate via the transition gear 85.

It should also be noted that, depending on actual needs, the second transmission mechanism 80 may also be other transmission mechanisms. For example, the second transmission mechanism 80 may be a mechanical transmission mechanism, such as a linkage transmission mechanism or a worm-gear transmission mechanism. The second transmission mechanism 80 may also be an electrical transmission mechanism that includes electrical equipment such as an electric motor or a cylinder.

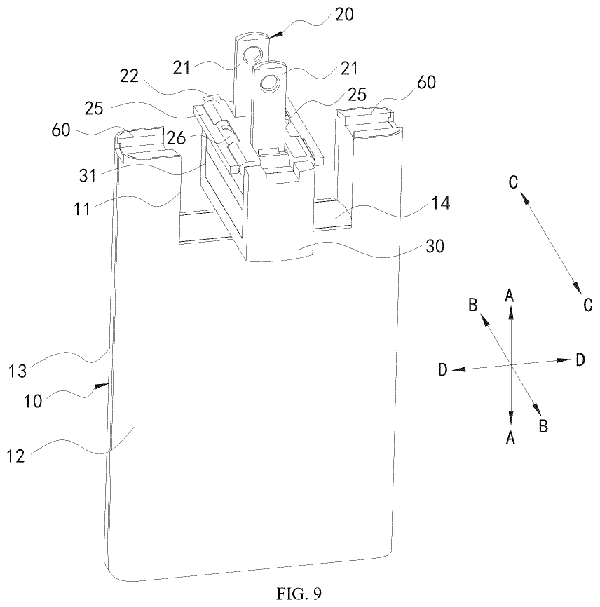

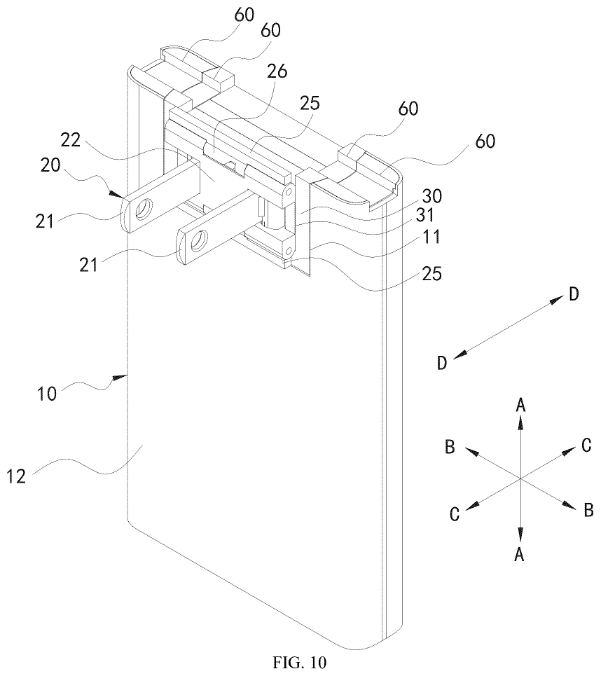

As illustrated in FIGS. 9 and 10, in some examples of the present disclosure, the plug further includes a rotary bracket 30 that is rotatably connected to the housing 10 about a first preset direction AA, and the pin assembly 20 is rotatably connected to the rotary bracket 30 about a second preset direction BB. The second preset direction BB, the first preset direction AA, and the axial direction of the first rotary shaft 24 are perpendicular to each other.

It should be noted that the rotary bracket 30 is configured to provide support for the pin assembly 20. The rotary bracket 30 may rotate relative to the housing 10 about the first preset direction AA, and the pin assembly 20 may rotate with the rotary bracket 30 about the first preset direction AA. In addition, the pin assembly 20 may also rotate relative to the rotary bracket 30 about the second preset direction BB. Therefore, the pin assembly 20 may rotate relative to the housing 10 about the first preset direction AA and the second preset direction BB, thereby enabling adjustment of positions of the pins 21 in multiple dimensions. When inserting the pins 21 into a power strip, the user may rotate the rotary bracket 30 and/or the pin assembly 20 according to distribution of jacks on the power strip to adjust the position of the pins 21. This allows the user to adjust the position of the housing 10 on the power strip after the pins 21 are inserted into the socket, so that the housing 10 gets away from vacant sockets on the power strip. This prevents the housing 10 from blocking adjacent jacks after the pins 21 are inserted into the socket, and also prevents the housing 10 from interfering with other electronic devices on the power strip.

Furthermore, referring to FIG. 3, taking the first preset direction AA parallel to a peripheral surface 12 of the housing 10 as an example, in scenarios where the power strip is placed vertically on a wall or table, when the pins 21 need to be inserted into the power strip, the pin assembly 20 may be rotated about the second preset direction BB. Therefore, when the pins 21 are inserted into the power strip, the housing 10 may be parallel to the power strip, thereby increasing a contact area between the housing 10 and the power strip and making the connection more stable, which can prevent the plug from separating from the power strip and causing the plug to fall off. It should also be noted that FIGS. 1 to 3 only illustrate a case where the first preset direction AA is parallel to the peripheral surface 12 of the housing 10, and the second preset direction BB may be set to be parallel to the peripheral surface 12 of the housing 10 depending on actual needs.

It should also be noted that when the first preset direction AA is parallel to the peripheral surface 12 of the housing 10, the axial direction of the second rotary shaft 26 is parallel to the second preset direction BB; when the second preset direction BB is parallel to the peripheral surface 12 of the housing 10, the axial direction of the second rotary shaft 26 is parallel to the first preset direction AA.

In some examples of the present disclosure, the housing 10 is provided with a first mounting recess 11. The first mounting recess 11 extends along a third preset direction CC and penetrates through the housing 10 to form a first avoidance opening for the rotary bracket 30 to rotate. The third preset direction CC is perpendicular to the first preset direction AA.

A movable trajectory of the rotary bracket 30 includes a first preset position (as illustrated in FIGS. 1 and 10) and a second preset position (as illustrated in FIG. 9). When the rotary bracket 30 is in the first preset position, the rotary bracket 30 is accommodated in the first mounting recess 11. When the rotary bracket 30 is in the second preset position, part of the rotary bracket 30 extends out of the first mounting recess 11 via the first avoidance opening. It should be noted that, as illustrated in FIG. 1, when the rotary bracket 30 is in the first preset position, the first mounting recess 11 may accommodate the rotary bracket 30, reducing the overall size of the plug and making the plug convenient to carry and store. The first avoidance opening may provide a rotation space for the rotary bracket 30, thereby avoiding the first mounting recess 11 limiting the rotation of the rotary bracket 30.

In an example, as illustrated in FIGS. 1 and 9, the first preset direction AA is parallel to the peripheral surface 12 of the housing 10, and the rotary bracket 30 may rotate 360 degrees about the first preset direction AA. The rotary bracket 30 rotates 90 degrees from the first preset position (as illustrated in FIG. 1) to the second preset position (as illustrated in FIG. 9).

In some examples of the present disclosure, the rotary bracket 30 is provided with a second mounting recess 31. The second mounting recess 31 extends along a fourth preset direction DD and penetrates through the rotary bracket 30 to form a second avoidance opening for the pin assembly 20 to rotate. The fourth preset direction DD is perpendicular to the second preset direction BB.

A movable trajectory of the pin assembly 20 includes a third preset position (as illustrated in FIGS. 1 and 9) and a fourth preset position (as illustrated in FIG. 10). When the pin assembly 20 is in the third preset position, the pin assembly 20 is accommodated in the second mounting recess 31. When the pin assembly 20 is in the fourth preset position, part of the pin assembly 20 extends out of the second mounting recess 31 through the second avoidance opening. It should be noted that, as illustrated in FIG. 1, when the pin assembly 20 is in the third preset position, the second mounting recess 31 may accommodate the pin assembly 20, further reducing the overall size of the plug and making the plug convenient to carry and store. The second avoidance opening may provide a rotation space for the pin assembly 20, thereby avoiding the second mounting recess 31 limiting the rotation of the pin assembly 20. It should also be noted that in FIGS. 1 and 10, the fourth preset direction DD is parallel to the third preset direction CC, while in FIG. 9, the fourth preset direction DD is perpendicular to the third preset direction CC.

In an example, as illustrated in FIGS. 1 and 10, the first preset direction AA is parallel to the peripheral surface 12 of the housing 10, and the pin assembly 20 may rotate 180 degrees about the first preset direction AA. The pin assembly 20 rotates 90 degrees from the third preset position (as illustrated in FIG. 1) to the fourth preset position (as illustrated in FIG. 10). When the pin assembly 20 rotates to the fourth preset position, the pin assembly 20 abuts a bottom wall of the second mounting recess 31 to prevent the pins 21 from continuing to rotate to a direction away from the third preset position.

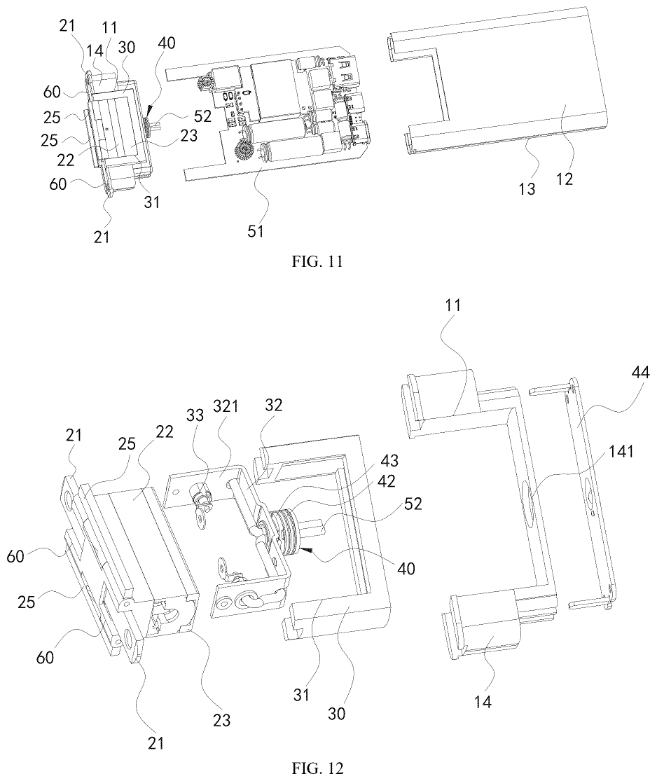

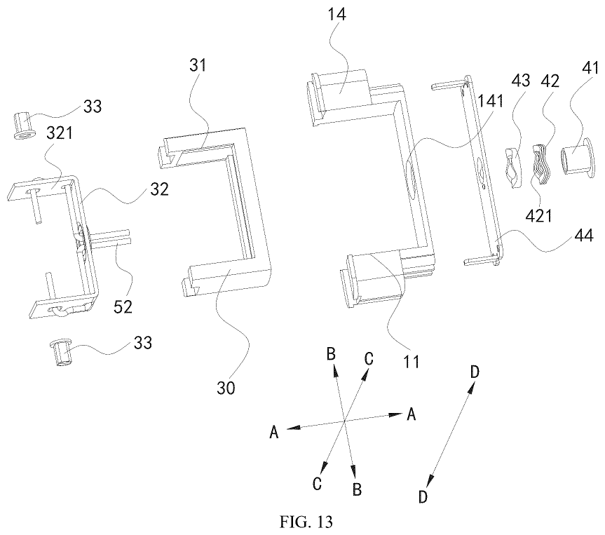

In some examples of the present disclosure, as illustrated in FIGS. 11 to 13, the housing 10 includes a main body 13 and a fixed bracket 14 that are detachably connected. The fixed bracket 14 is has the first mounting recess 11. The fixed bracket 14 may be detachably connected to the main body 13 by snap-fit or threaded connection. The rotary bracket 30 is mounted on the fixed bracket 14, and the fixed bracket 14 is configured to provide support for the rotary bracket 30.

Referring again to FIGS. 11 to 13, in some examples of the present disclosure, the first preset direction AA is parallel to the peripheral surface 12 of the housing 10. The plug further includes a rotary assembly 40, which includes a bushing 41 and a first elastic piece 42. The fixed bracket 14 is provided with a through hole 141 on a side close to the main body 13. An axial direction of the bushing 41 is parallel to the first preset direction AA. The bushing 41 extends into the through hole 141 and is connected to the rotary bracket 30. The rotary bracket 30 is rotatably connected to the housing 10 about the first preset direction AA via the bushing 41. The first elastic piece 42 is sleeved on the bushing 41.

An inner side of the first elastic piece 42 is provided with a concave-convex structure 421 extending around a circumference of the bushing 41. The concave-convex structure 421 includes a recessed portion and a protruding portion arranged along the circumference of the bushing 41. A distance between the protruding portion and the bushing 41 is smaller than a distance between the recessed portion and the bushing 41, so that the first elastic piece 42 provides different magnitudes of damping force for the bushing 41 when the bushing 41 rotates to different positions. This results in an obvious jerking sense during the rotation of the bushing 41. By designing the concave-convex structure 421, the rotation position of the rotary bracket 30 can be located. For example, when the rotary bracket 30 is in the first preset position and the second preset position, the damping force of the first elastic piece 42 on the bushing 41 is large, while when the rotary bracket 30 is in other positions, the damping force of the first elastic piece 42 on the bushing 41 is small. Whether the rotary bracket 30 is rotated to the first preset position and the second preset position can be determined according to the change in the damping force of the first elastic piece 42 on the bushing 41. A positioning piece 43 may limit the first elastic piece 42 to prevent the first elastic piece 42 from moving along the axial direction of the bushing 41 during use. A material used to prepare the first elastic piece 42 may be elastic metal, elastic rubber, elastic plastic or other materials, which is not specifically limited in the present disclosure.

In some examples of the present disclosure, the rotary assembly 40 further includes the positioning piece 43 and a positioning plate 44. The positioning piece 43 is sleeved on the bushing 41 and is located on a side of the first elastic piece 42 close to the fixed bracket 14. The positioning plate 44 is located on a side of the fixed bracket 14 away from the rotary bracket 30. The positioning plate 44 is mounted on the fixed bracket 14 and surrounds a periphery of the positioning piece 43. The positioning plate 44 is configured to fix the positioning piece 43 to the bushing 41, thereby using the positioning piece 43 to limit the first elastic piece 42 and prevent the first elastic piece 42 from moving along the axial direction of the bushing 41 during use.

Referring again to FIGS. 11 to 13, the rotary bracket 30 further includes an elastic bracket 32 located in the second mounting recess 31. The elastic bracket 32 includes second elastic pieces 321 located on both sides of the pin assembly 20 along the second preset direction BB. The pin assembly 20 is sandwiched between the two second elastic pieces 321, and the pin assembly 20 is rotatably connected to the second elastic pieces 321 about the second preset direction BB via a rotary arm 33. The second elastic pieces 321 may provide rotational resistance for the pin assembly 20, preventing the pin assembly 20 from rotating easily due to external forces during use. A material used to prepare the second elastic piece 321 may be elastic metal, elastic rubber, elastic plastic or other materials, which is not specifically limited in the present disclosure.

Referring again to FIGS. 11 to 13, in some examples of the present disclosure, the plug further includes a circuit board 51 and a conductive wire 52. The circuit board 51 is located inside the housing 10. One end of the conductive wire 52 passes through the bushing 41 and is electrically connected to the circuit board 51; the other end of the conductive wire 52 passes through the rotary arm 33 and is electrically connected to the pins 21. The circuit board 51 may be electrically connected to a device to be charged through a data cable or other connecting wires, thereby achieving electrical connection between the pins 21 and the device to be charged. The circuit board 51 may be a single-sided board, a double-sided board, or a multi-layer board. The present disclosure does not specifically limit the type, model, and size of the circuit board 51.

In some examples of the present disclosure, the pin assembly 20 further includes the mounting bracket 22 on which the pins 21 are mounted. The mounting bracket 22 is rotatably connected to the rotary bracket 30 about the second preset direction BB to switch between the third preset position and the fourth preset position.

In some examples of the present disclosure, the pin assembly 20 further includes a silicone seat 23, which is mounted on a side of the mounting bracket 22 close to the rotary bracket 30. The silicone seat 23 can serve as an insulator to prevent metal parts on the mounting bracket 22 from forming a short circuit with the conductive wire 52. The silicone seat 23 and the mounting bracket 22 may be integrally injection molded, and the silicone base 23 may also be assembled onto the mounting bracket 22 by gluing fixation.

The same or similar reference signs in the drawings of the examples correspond to the same or similar components. In description of the present disclosure, it should be understood that the terms “upper”, “lower”, “left”, “right”, and the like indicating orientation or position relationships are based on orientation or position relationships shown in the drawings, and are intended to describe the disclosure and simplify description only but not to indicate or imply that the referred device or element must have a particular orientation and be configured and operated in a particular orientation. Therefore, the terms used to describe position relationships are intended to be illustrative only but not to limit the present disclosure. For those skilled in the art, specific meanings of the above terms can be understood according to specific situations.

The above are only preferred examples of the present disclosure and are not intended to limit the disclosure. Any modifications, equivalent substitutions, improvements or the like within the spirit and principle of the disclosure should be included in the scope of the disclosure.

What is claimed is:

1. A plug comprising:
a housing; and
a pin assembly comprising two pins configured to switch between an unfolded position and a stored position,
wherein in response to one of the two pins rotating to the unfolded position, the other one of the pins is driven to rotate in an opposite direction toward the unfolded position, and in response to the one of the two pins rotating to the stored position, the other one of the pins is driven to rotate in an opposite direction toward the stored position.

2. The plug of claim 1, further comprising:
a mounting bracket connected to the housing, wherein the two pins are rotatably connected to the mounting bracket via two rotary shafts.

3. The plug of claim 2, further comprising:
a transmission mechanism disposed on the mounting bracket, wherein the two pins are in transmission connection via the transmission mechanism, and in response to rotation of the one of the two pins, the other one of the two pins is driven to rotate via the transmission mechanism.

4. The plug of claim 3, wherein the transmission mechanism comprises:
a first driving gear connected to one of the two rotary shafts, wherein an axial direction of the first driving gear is parallel to an axial direction of the one of the two rotary shafts;
a second driving gear connected to the other one of the two rotary shafts, wherein an axial direction of the second driving gear is parallel to an axial direction of the other one of the two rotary shafts;
a first transmission gear rotatably connected to the mounting bracket about an axial direction of the first transmission gear, wherein the axial direction of the first transmission gear is parallel to the axial direction of the one of the two rotary shafts, and wherein the first transmission gear meshes with the first driving gear; and
a second transmission gear rotatably connected to the mounting bracket about an axial direction of the second transmission gear, wherein the axial direction of the second transmission gear is parallel to the axial direction of the other one of the two rotary shafts, and wherein the second transmission gear meshes with the first transmission gear and the second driving gear.

5. The plug of claim 4, wherein the pin assembly further comprises:
safety members disposed on two sides of the two pins and at edges of the mounting bracket, and wherein the safety members are configured to increase a length of the pins along an axial direction of the two rotary shafts.

6. The plug of claim 5, wherein one of the safety members is rotatably connected to the mounting bracket via a second rotary shaft to switch between a distance-increasing position and a distance-decreasing position, an axial direction of the second rotary shaft being perpendicular to the axial direction of the two rotary shafts; and
when the one of the safety members is in the distance-increasing position, a length of the two pins along the axial direction of the two rotary shafts is greater than a length of the two pins along the axial direction of the two rotary shafts when the one of the safety members is in the distance-decreasing position.

7. The plug of claim 6, wherein:
the pin assembly further comprises a second transmission mechanism disposed on the mounting bracket,
the two rotary shafts are in transmission connection with the second rotary shaft via the second transmission mechanism,
in response to rotation of the two rotary shafts, the second rotary shaft is driven to rotate via the second transmission mechanism, such that when the two pins rotate to the unfolded position, the safety members are driven to rotate to the distance-increasing position, and when the two pins rotate to the stored position, the safety members are driven to rotate to the distance-decreasing position.

8. The plug of claim 7, wherein the second transmission mechanism comprises:
a third driven gear rotatably connected to the mounting bracket about an axial direction of the third driven gear, and in transmission connection with the two rotary shafts, wherein the axial direction of the third driven gear is parallel to the axial direction of the two rotary shafts, and when the two rotary shafts rotate, the third driven gear is driven to rotate; and
a rack slidably connected to the mounting bracket along the axial direction of the second rotary shaft and meshing with the third driven gear.

9. The plug of claim 8, further comprising:
a slide rod connected to the rack,
a slide groove provided in a circumferential surface of the second rotary shaft, wherein:
the slide groove extends along the axial direction and a circumferential direction of the second rotary shaft,
the slide rod is inserted into the slide groove, and
when the rack slides along the axial direction of the second rotary shaft, the slide rod slides along the slide groove to drive the second rotary shaft to rotate about the axial direction of the second rotary shaft.

10. The plug of claim 8, wherein the second transmission mechanism further comprises:
a transition gear coaxially disposed and fixedly connected with the first transmission gear or the second transmission gear and meshes with the third driven gear, and wherein at least one of the rotary shafts is in transmission connection with the third driven gear via the transition gear.

11. A plug comprising:
a housing; and
a pin assembly comprising a mounting bracket and two pins, wherein the mounting bracket is connected to the housing, and the two pins are rotatably connected to the mounting bracket via two rotary shafts to switch between an unfolded position and a stored position; and
a rotary bracket rotatably connected to the housing about a first preset direction,
wherein the pin assembly is rotatably connected to the rotary bracket about a second preset direction, and the second preset direction, the first preset direction, and an axial direction of the two rotary shafts are perpendicular to each other.

12. The plug of claim 11, wherein:
at least one of the housing and the mounting bracket comprises an accommodating recess,
when the rotary bracket is in the stored position, the accommodating recess is configured to accommodate the two pins, and
when the two pins are in the unfolded position, the two pins extend in a direction away from a bottom wall of the accommodating recess, and at least a portion of the two pins is located outside the accommodating recess.

13. The plug of claim 11, wherein the housing comprises a main body and a fixed bracket that are detachably connected, and the rotary bracket is mounted on the fixed bracket.

14. The plug of claim 13, further comprising a rotary assembly comprising a bushing and a first elastic piece, wherein:
a side of the fixed bracket close to the main body comprises a through hole,
an axial direction of the bushing is parallel to the first preset direction,
the bushing extends into the through hole and is connected to the rotary bracket,
the rotary bracket is rotatably connected to the housing about the first preset direction via the bushing, and
the first elastic piece is sleeved on the bushing.

15. The plug of claim 14, wherein:
an inner side of the first elastic piece comprises a concave-convex structure extending around a circumference of the bushing,
the concave-convex structure comprises a recessed portion and a protruding portion arranged along the circumference of the bushing,
a distance between the protruding portion and the bushing is smaller than a distance between the recessed portion and the bushing, so that the first elastic piece provides different magnitudes of damping force for the bushing when the bushing rotates to different positions.

16. The plug of claim 11, wherein the housing comprises a first mounting recess, and the first mounting recess extends along a third preset direction perpendicular to the first preset direction and penetrates through the housing to form a first avoidance opening for the rotary bracket to rotate.

17. The plug of claim 16, wherein:
a movable trajectory of the rotary bracket comprises a first preset position and a second preset position,
when the rotary bracket is in the first preset position, the rotary bracket is accommodated in the first mounting recess, and
when the rotary bracket is in the second preset position, part of the rotary bracket extends out of the first mounting recess via the first avoidance opening.

18. The plug of claim 11, wherein the rotary bracket comprises a second mounting recess, and the second mounting recess extends along a fourth preset direction perpendicular to the second preset direction and penetrates through the rotary bracket to form a second avoidance opening for the pin assembly to rotate.

19. The plug of claim 18, wherein:
a movable trajectory of the mounting bracket comprises a third preset position and a fourth preset position,
when the mounting bracket is in the third preset position, the mounting bracket is accommodated in the second mounting recess, and
when the mounting bracket is in the fourth preset position, part of the mounting bracket extends out of the second mounting recess through the second avoidance opening.

20. The plug of claim 18, wherein:
the rotary bracket further comprises an elastic bracket located in the second mounting recess,
the elastic bracket comprises second elastic pieces located on both sides of the pin assembly along the second preset direction,
the pin assembly is sandwiched between the second elastic pieces, and
the pin assembly is rotatably connected to the second elastic pieces about the second preset direction via a rotary arm.
